(19) United States
(12) Patent Application Publication
(10) Pub. No.: US 2019/0244787 A1
(43) Pub. Date: Aug. 8, 2019

(54) PLASMA ETCHING REACTION CHAMBER

(71) Applicants: Wei-Chuan Chou, Taipei City (TW); Zhi Kai Huang, Taipei City (TW); Mu-Chun Ho, Taipei City (TW); Chun-Fu Wang, Taipei City (TW); Yi-Hsiang Chen, Taipei City (TW); Hsin-Chih Chiu, Taipei City (TW); Yao-Syuan Cheng, Taipei City (TW)

(72) Inventors: Wei-Chuan Chou, Taipei City (TW); Zhi Kai Huang, Taipei City (TW); Mu-Chun Ho, Taipei City (TW); Chun-Fu Wang, Taipei City (TW); Yi-Hsiang Chen, Taipei City (TW); Hsin-Chih Chiu, Taipei City (TW); Yao-Syuan Cheng, Taipei City (TW)

(21) Appl. No.: 15/886,844

(22) Filed: Feb. 2, 2018

(51) Int. Cl. H01J 37/32

(52) U.S. Cl. CPC H01J 37/32082; H01J 2237/334; H01J 37/32532

(57) ABSTRACT

A plasma etching reaction chamber includes a casing having a receiving chamber; a base liftably installed below the receiving chamber; a first electrode and a second electrode; and a radio frequency electrode rod. The second electrode has a plurality of water channels and a bottom of the second electrode is installed with two cooling water tubes which are communicated with the plurality of water channels; upper sides of the two cooling water tubes are hidden within the driving rod and lower sides thereof extend downwards to be out of the casing so that external cooling water can flow into the cooling water tubes and then to the water channels to achieve the object of cooling.

### FIELD OF THE INVENTION

The present invention is related to wafer making process, and in particular to a plasma etching reaction chamber.

### BACKGROUND OF THE INVENTION

In semiconductor flip chip process, packaging and fan out package, before electric plating, a physical gas deposition sputtering is used to made a metal barrier, however, before forming the metal layer, a plasma cleanness process is made, in that, plasma bombardment is used to remove the oxide and some minor undesired objects on the aluminum electrode of the chip.

In the plasma cleanness process, some slide sub-products will be generated, such as PI, PBO, carbon and other micro particles, or gas sub-products, such as CO, CO2, O2, water, etc. Some of these sub-products will be sucked out by turbine pumps, some will stick on an inner shielding plate of a plasma etching reaction chamber, while there still are some of them which are dispersed within the reaction chamber and then pollute the wafers in the chamber so as to cause defects of aluminum electrodes by particle form of the sub-products, or increase the contact resistance of the aluminum electrodes.

Currently, ways to resolve such problem are to increase the suction efficiency of the turbine pump so as to draw the particles out of the chamber quickly or the coarseness of the inner shielding plate is increased so as to absorb more particles or sub-products. However, these ways have finite effects. If the requirement for manufacturing process is very high, these ways cannot support the requirements.

Sometime, an aluminum sheet (may be formed by aluminum which has a shape like a wafer or by electrical plating aluminum on a wafer) is transferred into a chamber and then it is bombarded by plasma so that the aluminum particles are released out and then they are combined with the sub-products on the air to form as steady chemical compounds or aluminum is plated on the shielding plate to absorb the particles, and thus to effectively reduce the sub-products in the reaction chamber. For this process, generally, the aluminum sheets used are finite (preferably seven sheets) and then another process for adding aluminum sheets or plating aluminum is performed.

### SUMMARY OF THE INVENTION

Accordingly, the object of the present invention is to provide a plasma etching reaction chamber which can effectively improve the pollution within the chamber and has no the prior art defects as said above.

To achieve above object, the present invention provides a plasma etching reaction chamber, comprising: a casing having a receiving chamber; an inner periphery and a bottom of the receiving chamber being formed with respective inner shielding plates for sticking the sub-products generated in the process of plasma cleaning; a base liftably installed below the receiving chamber; a bottom of the base being extended with a driving rod; the driving rod extending downwards to pass through the casing; a driving unit serving to drive the base to move upwards or downwards; a first electrode installed in an upper side of the receiving chamber; a second electrode installed on the base for supporting a wafer; a radio frequency electrode rod installed on a bottom of the second electrode; an upper side of the radio frequency electrode rod being within the driving rod and a lower side of the radio frequency electrode rod extending downwards to expose out of the driving rod and extending out of the casing to be connected to a radio frequency power supply (not shown) for supplying RF power into the second electrode so that the first electrode and the second electrode can generate plasma therebetween; wherein the second electrode has a plurality of water channels and a bottom of the second electrode is installed with two cooling water tubes which are communicated with the plurality of water channels; upper sides of the two cooling water tubes are hidden within the driving rod and lower sides thereof extend downwards to be out of the casing so that external cooling water can flow into the cooling water tubes and then to the water channels to achieve the object of cooling.

### BRIEF DESCRIPTION OF THE DRAWINGS

FIG. 1 is a perspective view the casing of the present invention.

FIG. 2 is a schematic view of the present invention.

FIG. 3 is a schematic view showing the operation action of the present invention.

FIG. 4 is a schematic view showing another action according to The present invention.

FIG. 5 shows another embodiment of the present invention.

FIG. 6 is a time sequence showing the action of the electrodes.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

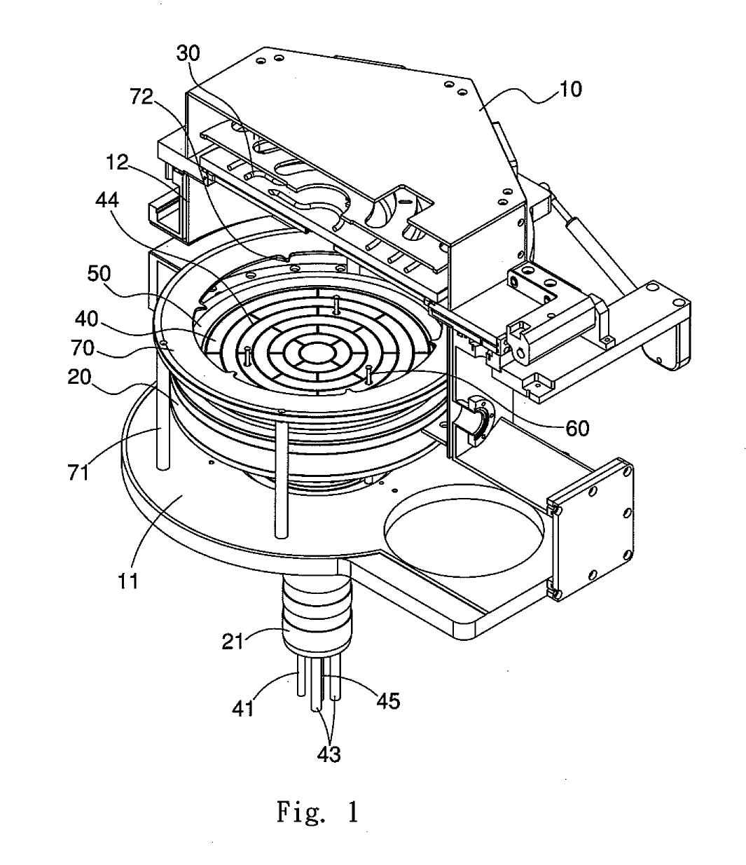

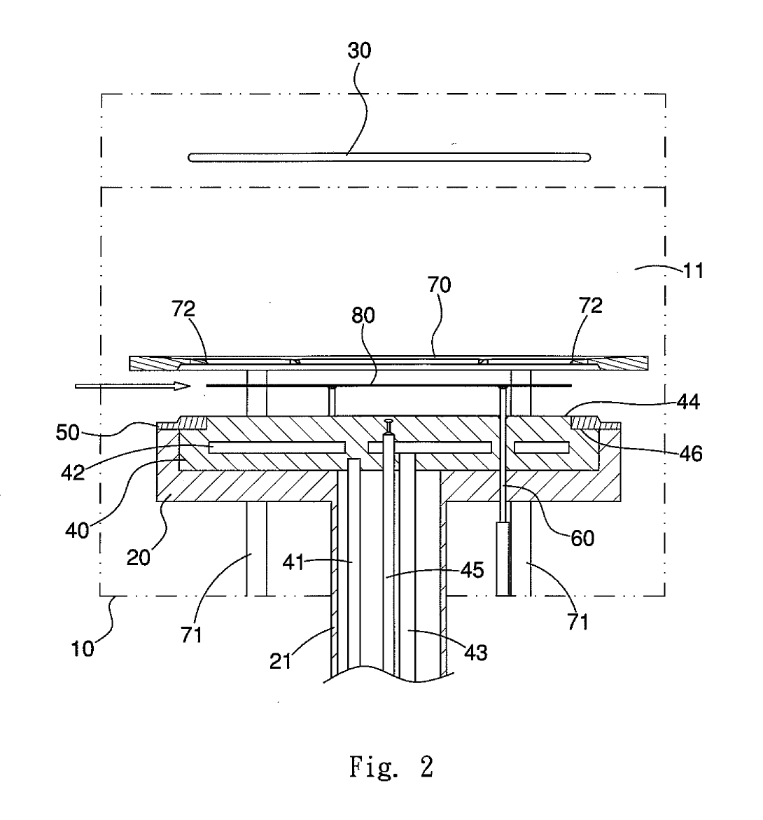

With reference to FIGS. 1 and 2, the improved structure about the plasma etching reaction chamber of the present invention includes the following elements.

A casing 10 has a receiving chamber 11 therein. An inner periphery and a bottom of the receiving chamber 11 are formed with respective inner shielding plates 12 for sticking the sub-products generated in the process of plasma cleaning.

A base 20 is liftably installed below the receiving chamber 11. A bottom of the base 20 is extended with a driving rod 21. The driving rod 21 extends downwards to pass through the casing 10. A driving unit (not shown) serves to drive the base 20 to move upwards or downwards.

A first electrode 30 is installed in an upper side of the receiving chamber 11.

A second electrode 40 is installed on the base 20 for supporting a wafer 80.

A radio frequency electrode rod 41 is installed on a bottom of the second electrode 40. An upper side of the radio frequency electrode rod 41 is within the driving rod 21 and a lower side of the radio frequency electrode rod 41 extends downwards to expose out of the driving rod 21 and extends out of the casing 10 to be connected to a radio frequency power supply (not shown) for supplying RF power into the second electrode 40 so that the first electrode 30 and the second electrode 40 can generate plasma therebetween.

The second electrode 40 has a plurality of water channels 42 and a bottom of the second electrode 40 is installed with two cooling water tubes 43 which are communicated with the plurality of water channels 42. Upper sides of the two cooling water tubes 43 are hidden within the driving rod 21 and lower sides thereof extend downwards to be out of the casing 10 to be connected to an ice water machine (not shown) so that cooling water can flow into the cooling water tubes 43 and then to the water channels 42 to achieve the object of cooling.

A top the second electrode 40 is arranged with a plurality of trenches 44 and a bottom side of the second electrode 40 extends with an air inlet tube 45 which are communicated with the plurality of trenches 44. The air inlet tube 45 extends out of the casing 10 through the driving rod 21 for guiding argon into the plurality of trenches 44 for heat convection in the reaction process so as to transfer heat on a surface of the wafer 80 to the second electrode 40 and then water in the plurality of water channels 42 will dissipate the heat so as to cool the wafer 80. An upper periphery of the second electrode 40 has an annular groove 46.

An aluminum ring 50 has an annular shape and is installed on the base 20 and is embedded into the annular groove 46 of the second electrode 40 so as to be arranged on a periphery of the second electrode 40.

A plurality of ejecting rods 60 is arranged. Lower ends of the ejecting rods 60 are installed on the lower surface of the receiving chamber 11 and upper ends of the ejecting rods 60 pass through the base 20 and the second electrode 40. Each ejecting rod 60 is movable upwards and downwards so as to place the wafer 80 on a top of the second electrode 40 or cause the wafer 80 to have a distance from the second electrode 40.

A press ring 70 has an annular shape and a bottom thereof is extended downwards with a plurality of supporting posts 71 for supporting the press ring 71 in a predetermined height. An inner diameter of the press ring 70 is greater than an inner diameter of the aluminum ring 50. An inner side of the press ring 70 is protruded with a plurality of protrusions 72. When the base 20 is lifted to a predetermined height, the plurality of protrusions 72 will fix the wafer 80 and a part of the aluminum ring 50 exposes out of the inner side of the press ring 70.

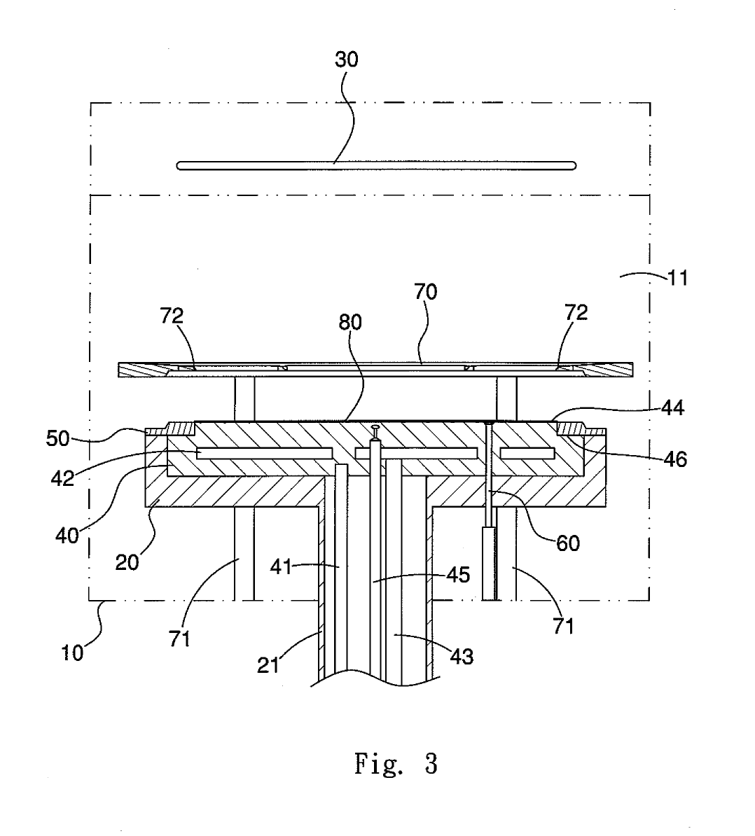

In the present invention, during plasma cleanness, an outer robot (not shown) will transfer the wafer 80 into the receiving chamber 11. The plurality of ejecting rods 60 are lifted upwards to resist against the wafer 80 so that the robot will leave from the wafer 80 (referring to FIG. 2). Then the plurality of ejecting rods 60 descends to place the wafer 80 on a top surface of the second electrodes 40 (referring to FIG. 3). Then, the driving rod 21 drives the base 20 to a predetermined height so that the protrusions 72 of the plurality of the press ring 70 fixes the wafer 80 to the top surface of the second electrodes 40. Then an air tube (not shown) communicated the receiving chamber 11 to outer side will cause argon to enter into the receiving chamber 11 until the air pressure of the receiving chamber 11 is increased to a pressure which is suitable for the action of plasma. Then the argon is transferred to the plurality of trenches 44 through the air inlet tube 45 so that a bottom of the wafer 80 forms a partial air layer with a pressure of about 45 torrs.

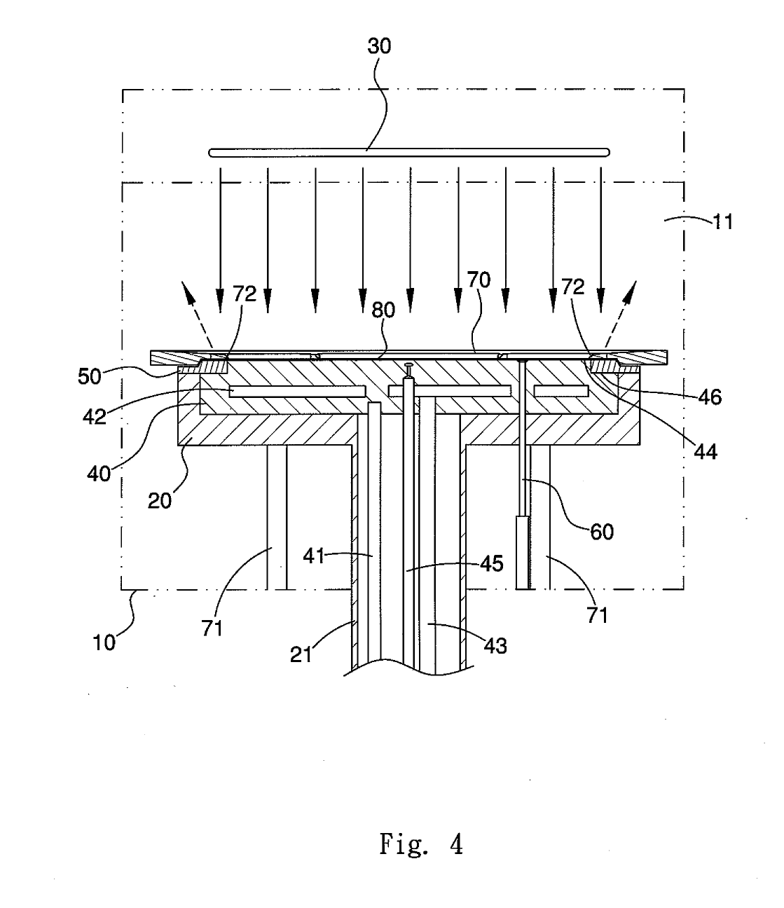

Then plasma is generated between the second electrode 40 and the first electrode 30. By the plasma, the oxides and some micro pollution particles on the wafer 80 will be removed so that plasma cleanness can be performed. Meanwhile, the aluminum molecules on the surface of the aluminum ring 50 will release out to combine with air form sub-products so the air form sub-product will not pollute surface of the wafer 80. Besides, the aluminum molecules are plated on the inner shielding plate 12 of the casing 10 so that part of the sub-products are fixed and thus not induce pollution within the chamber (referring to FIG. 4). Therefore when the wafer 80 is cleaned, above action are done reversely to transfer the wafer 80 out of the chamber. Therefore, the pollution from the sub-products during the cleaning process of plasma is avoided. Furthermore the period for aluminum attachment is prolonged and thus the working efficiency is promoted.

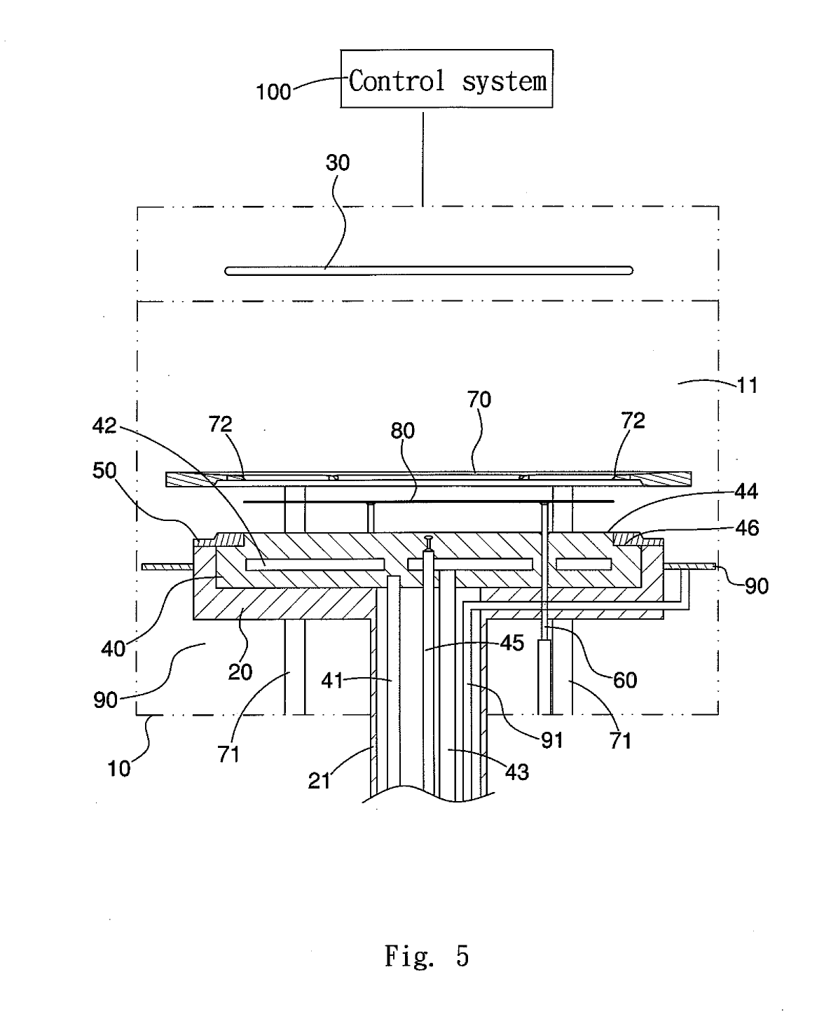

FIG. 5 shows another embodiment about the cleanness of plasma etching reaction chamber. The structure in the second embodiment is almost identical those shown in the first embodiment. Therefore, for the elements indicated with same numerals having the same functions will not be described herein. In this embodiment, the present invention further includes an annular aluminum plate 90, a third electrode 91 and a control system 100.

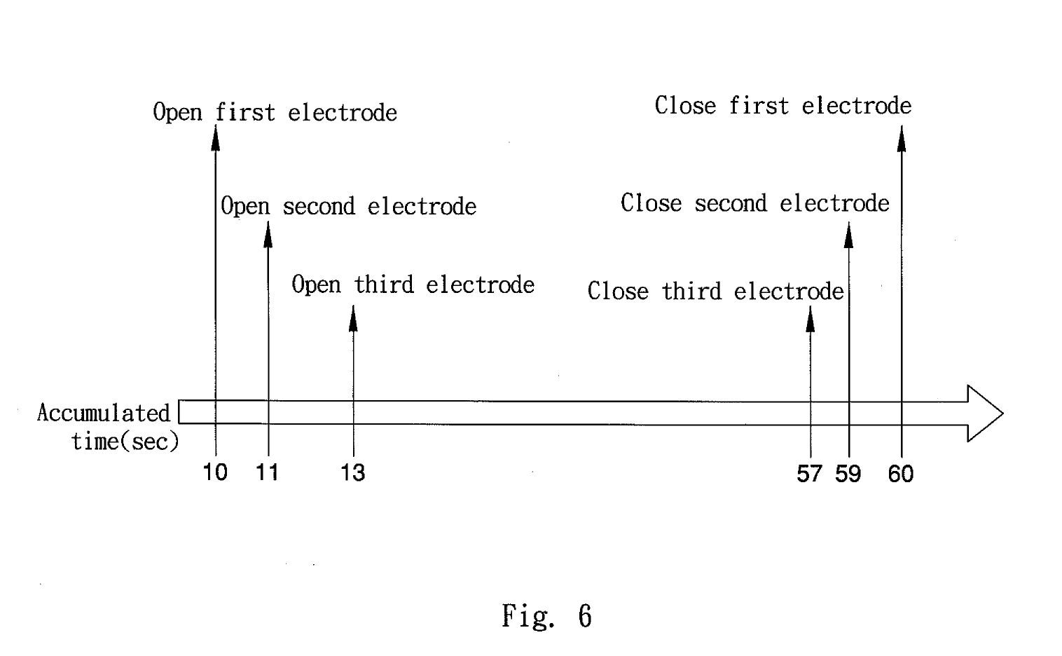

The annular aluminum plate 90 is installed in the periphery of the base 20, and one end of the third electrode 91 is connected to a bottom of the annular aluminum plate 90 and another end thereof passes through the base 20 and then extended to externals through the driving rod 21. It can generate plasma with the first electrode 30 so as to release the aluminum molecules on the surface of the annular aluminum plate 90 to increase the effect of aluminum attachment. The control system serves to control the electricity of first electrode 30, the second electrode 40 and the third electrode 91. For example, the control system 100 will control the third electrode 91 to conduct to be later than the conduction of the first electrode 30 and the second electrode 40 and not to conduct to be earlier than that of the first electrode 30 and the second electrode 40 (referring to FIG. 6) so as to assure that the aluminum molecules released from aluminum ring 50 will not pollute the wafer 80.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A plasma etching reaction chamber, comprising:
a casing having a receiving chamber; an inner periphery and a bottom of the receiving chamber being formed with respective inner shielding plates for sticking the sub-products generated in the process of plasma cleaning;
a base liftably installed below the receiving chamber; a bottom of the base being extended with a driving rod; the driving rod extending downwards to pass through the casing; a driving unit serving to drive the base to move upwards or downwards;
a first electrode installed in an upper side of the receiving chamber;
a second electrode installed on the base for supporting a wafer;
a radio frequency electrode rod installed on a bottom of the second electrode; an upper side of the radio frequency electrode rod being within the driving rod and a lower side of the radio frequency electrode rod extending downwards to expose out of the driving rod and extending out of the casing for supplying externally RF power into the second electrode so that the first electrode and the second electrode can generate plasma therebetween; and
wherein the second electrode has a plurality of water channels and a bottom of the second electrode is installed with two cooling water tubes which are communicated with the plurality of water channels; upper sides of the two cooling water tubes are hidden within the driving rod and lower sides thereof extend downwards to be out of the casing so that external cooling water can flow into the cooling water tubes and then to the water channels to achieve the object of cooling.

2. The plasma etching reaction chamber as claimed in claim 1, wherein a top of the second electrode is arranged with a plurality of trenches and a bottom side of the second electrode extends with an air inlet tube which are communicated with the plurality of trenches; the air inlet tube extends out of the casing through the driving rod for guiding argon into the plurality of trenches for heat convection in the reaction process so as to transfer heat on a surface of the wafer to the second electrode and then water in the plurality of water channels will dissipate the heat to cool the wafer; an upper periphery of the second electrode has an annular groove.

3. The plasma etching reaction chamber as claimed in claim 1, wherein an aluminum ring has an annular shape and is installed on the base and is embedded into the annular groove of the second electrode so as to be arranged on a periphery of the second electrode.

4. The plasma etching reaction chamber as claimed in claim 1, further comprising a plurality of ejecting rods; lower ends of the ejecting rods being installed on the lower surface of the receiving chamber and upper ends of the ejecting rods passing through the base and the second electrode; each ejecting rod being movable upwards and downwards so as to place the wafer on a top of the second electrode or cause the wafer to have a distance from the second electrode.

5. The plasma etching reaction chamber as claimed in claim 1, further comprising a press ring having an annular shape and a bottom thereof being extended downwards with a plurality of supporting posts for supporting the press ring in a predetermined height; an inner diameter of the press ring being greater than an inner diameter of the aluminum ring; an inner side of the press ring being protruded with a plurality of protrusions; wherein when the base is lifted to a predetermined height, the plurality of protrusions will fix the wafer and a part of the aluminum ring exposes out of the inner side of the press ring.

6. The plasma etching reaction chamber as claimed in claim 1, further comprising an annular aluminum plate, a third electrode and a control system; wherein the annular aluminum plate is installed in the periphery of the base, and one end of the third electrode is connected to a bottom of the annular aluminum plate and another end thereof passes through the base and then extended to externals through the driving rod; it can generate plasma with the first electrode so as to release the aluminum molecules on the surface of the annular aluminum plate to increase the effect of aluminum attachment; and the control system serves to control the electricity of first electrode, the second electrode and the third electrode.
